(19) United States
(12) Patent Application Publication
(10) Pub. No.: US 2018/0358478 A1
(43) Pub. Date: Dec. 13, 2018

(54) TRENCH TYPE JUNCTION BARRIER SCHOTTKY DIODE WITH VOLTAGE REDUCING LAYER AND MANUFACTURING METHOD THEREOF

(71) Applicants: NA REN, LOS ANGELES, CA (US); ZHENG ZUO, CULVER CITY, CA (US); RUIGANG LI, FREMONT, CA (US)

(72) Inventors: NA REN, LOS ANGELES, CA (US); ZHENG ZUO, CULVER CITY, CA (US); RUIGANG LI, FREMONT, CA (US)

(73) Assignee: AZ Power, Inc, CULVER CITY, CA (US)

(21) Appl. No.: 16/005,557

(22) Filed: Jun. 11, 2018

Related U.S. Application Data
(60) Provisional application No. 62/517,358, filed on Jun. 9, 2017.

(51) Int. Cl. H01L 29/872; H01L 29/06; H01L 29/16; H01L 21/04; H01L 29/45; H01L 29/66; H01L 21/02

(52) U.S. Cl. CPC H01L 29/872; H01L 29/0657; H01L 29/1608; H01L 21/0475; H01L 29/45; H01L 29/6606; H01L 29/66143; H01L 21/0485; H01L 21/0495; H01L 21/02529; H01L 21/02378; H01L 21/02634; H01L 21/046

(57) ABSTRACT

In one aspect, a method of manufacturing a trench type Schottky diode may include steps of providing a substrate, depositing an epitaxial layer on top of the substrate, forming one or more trenches on top of the epitaxial layer, forming a first implantation region in a bottom portion of each trench, forming a second implantation region in a sidewall portion of the trench, depositing an ohmic contact metal on an opposite side of the substrate, and depositing a Schottky contact metal on top of the epitaxial layer and filling the Schottky contact metal in each trench. In one embodiment, the substrate is made by an N⁺ type SiC, and the epitaxial layer is made by an N-type SiC on top of the substrate. In another embodiment, the first implantation region can be doped with P-type impurity and the second implantation region can be doped with N-type impurity.

### CROSS-REFERENCE TO RELATED APPLICATIONS

This application claims priority under 35 U.S.C. § 119 (e) to U.S. Provisional Patent Application Ser. No. 62/517,358, filed on Jun. 9, 2017, the entire contents of which are hereby incorporated by reference.

### FIELD OF THE INVENTION

The present invention relates to a trench type junction barrier Scthottky diode with a voltage reducing layer.

### BACKGROUND OF THE INVENTION

Silicon power devices have reached the physical limit. New wide-band-gap materials emerge recently, among which, silicon carbide (SiC) is more attractive for high voltage, high frequency and high temperature applications due to its superior physical and electrical parameters. The first commercialized device for SiC is Schottky barrier diodes (SBD). When compared with the traditional Si bipolar type PN diodes, SiC SBD diodes have advantages of no reverse recovery current and high frequency capability. With only one carrier conducting current in forward mode, it can eliminate the minor carrier injection phenomenon which is the condition for Si PN diodes. As a result, the reverse recovery process is eliminated upon switching and the switching loss can be reduced drastically.

For pure Schottky barrier diode, the relatively large leakage current is the main problem. Junction barrier Schottky (JBS) diode structure was proposed to address this problem, which combines the advantages of Schottky junction and PN junction diodes. In JBS structure, plurality of P regions is disposed between Schottky regions. The depletion layer diffuses from PN junction to exhibit pinch-off below the Schottky contact in reverse blocking mode, which can provide electric field shielding effect. As a result, the electric field strength at the Schottky interface can be reduced and the diode leakage current can be decreased subsequently.

The electric field shielding effect can be enhanced by increasing the PN junction depth. However, due to the strong lattice of SiC material, the ion implantation depth is restricted to be less than 1 μm. Recently, a trench type junction barrier Schottky diode structure is proposed as shown in FIG. 3. With the introduction of trench, the p-type ions can be implanted into the sidewall and bottom of the trench, and the subsequent PN junction can be deeper than 1 μm. However, in normal forward mode, only the Schottky junction in JBS structure can conduct current since the PN junction has a high onset voltage due to the wide band-gap of SiC. The depletion region from the PN junction will shrink the conduction channel to be much narrower than the design width of the Schottky region. As a result, with a deeper PN junction, the device forward performance will be sacrificed due to a higher channel resistance between adjacent P regions.

### SUMMARY OF THE INVENTION

In the trench type junction barrier Schottky diode, in order to increase forward current density while keep the strong electric field shielding effect introduced by the deep PN junction, it is necessary to induce a voltage reducing layer in the structure. Compared with common trench type junction barrier Schottky diode, N-type impurity is implanted into the sidewall of the trench to form low barrier Schottky junction between the trench layer and the epitaxial layer. As a result, the device forward current density can be increased. On the other hand, the P-type region in the bottom of the trench is remained for the reverse benefits with the electric field shielding effects.

In one aspect, a method of manufacturing a trench type junction barrier Schottky diode comprising: a silicon carbide substrate containing an impurity and having a first conduction type; an epitaxial layer of a first conduction type formed over the substrate and having an impurity concentration lower than that of the substrate; a group of first trenches each formed in the surface of the epitaxial layer and having a bottom and a sidewall; a second conduction type impurity region formed in the bottom side of the first trench; a first conduction type impurity region, i.e., the voltage reducing layer formed in the sidewall of the first trench; a first Schottky contact metal put on the top of the epitaxial layer; the first Schottky contact metal filling into the first trench to form Schottky junction between the trench layer and the epitaxial layer; and an ohmic contact formed on the rear face of the substrate, the method including: forming trenches with vertical walls by dry etching; and ion implanting a second conduction type impurity to the bottom of the first trench vertically to the surface of the substrate, thereby forming a second conduction type impurity region in the bottom of the first trench; forming a first conduction impurity region in the sidewall of the first trench; depositing the first Schottky metal onto the surface of the epitaxial layer to form Schottky junction on the top of the epitaxial layer; filling the first Schottky metal into the first trench, thereby forming Schottky junction between the trench and epitaxial layer.

Thus, in the present invention, even when the PN junction depth is increased intending to enhance the electric field shielding effect and lower the leakage current, forward current density can still be increased with the voltage reducing layer in the trench.

### BRIEF DESCRIPTION OF THE DRAWINGS

FIG. 1 is a cross sectional structural view of a trench type junction barrier Schottky diode with voltage reducing layer;

FIG. 2A to 2F are explanatory views for manufacturing processes of the trench type junction barrier Schottky diode;

FIG. 3 is a flow diagram of the method of manufacturing a trench type junction barrier Schottky diode with voltage reducing layer in the present invention.

FIG. 4 is a prior art showing a cross sectional structural view of a conventional trench type junction barrier Schottky diode.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

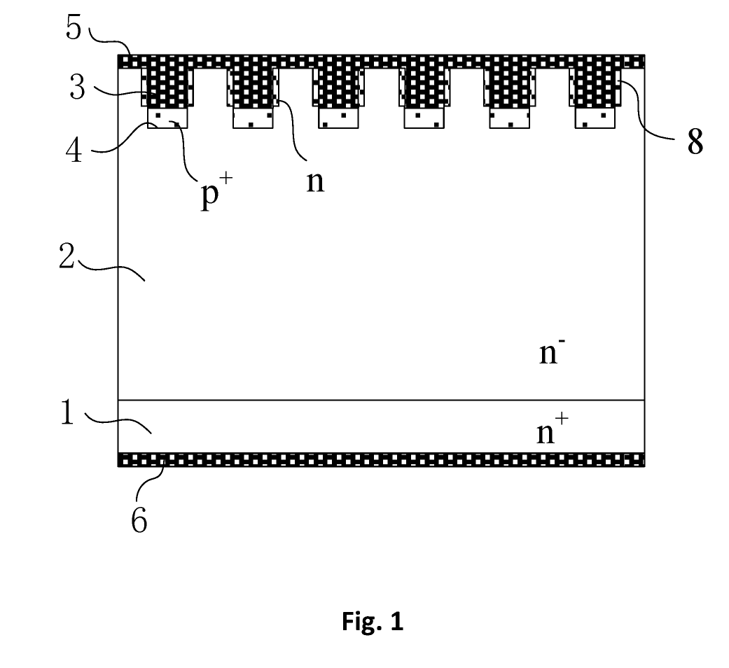

In one aspect as shown in FIG. 1, a cross sectional view of the SiC trench type junction barrier Schottky diode is illustrated. More specifically, the invention is related to a SiC trench type Schottky diode, which includes a substrate 1, an epitaxial layer 2, one or more trenches 3 on the epitaxial layer 2, a first implantation region 4, Schottky contact metal 5, ohmic contact metal 6 and a second implantation region 8. In one embodiment, the first implantation region 4 can be doped with P-type material such as boron or aluminum, and the second implantation region 8 can be doped with N-type material.

In another embodiment, the ohmic contact metal 6 can be selected from nickel, silver or platinum. In still another embodiment, the substrate 1 made by N⁺ type SiC is located on top of ohmic contact metal 6, and the epitaxial layer 2 made by N-type SiC is located on top of the substrate 1.

In a further embodiment, each trench 3 is formed by etching the epitaxial layer 2 with the depth of about 1˜50000 angstrom. The implantation region 4 is formed by ion implantation into the trench bottom with P-type material such as boron or aluminum. The thickness of the implantation region 4 is about 1˜10000 angstrom. The N-type implantation region 8 is also formed by ion implantation into the sidewall of the trench 3 with N-type material such as nitrogen or phosphorus. The thickness of the N-type implantation region 8 is about 1˜10000 angstrom.

The Schottky contact metal 5 is located on the top of the epitaxial layer 2. A Schottky junction is formed between the Schottky contact metal 5 and the epitaxial layer 2. The trench 3 is filled with the Schottky contact metal 5 and a Schottky junction is also formed between the trench 3 and the N-type implantation region 8.

It is important to note that the trench type junction barrier Schottky diode with a voltage reducing layer in the present invention can be used to improve the forward current density without deteriorating the reverse performance. Compared with common trench type junction barrier Schottky diode, the N-type impurity is implanted into the sidewall of the trench to form a voltage reducing layer. As a result, the Schottky barrier between the trench layer and the epitaxial layer can be controlled and the device forward voltage drop can be reduced then. Furthermore, the P-type region in the bottom of the trench is remained for the reverse benefits with the electric field shielding effects.

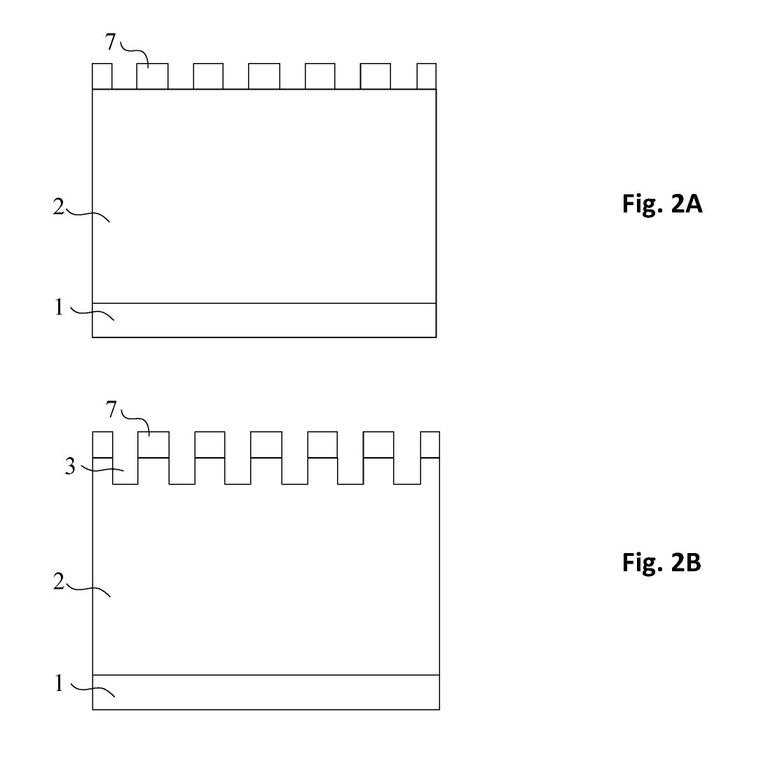

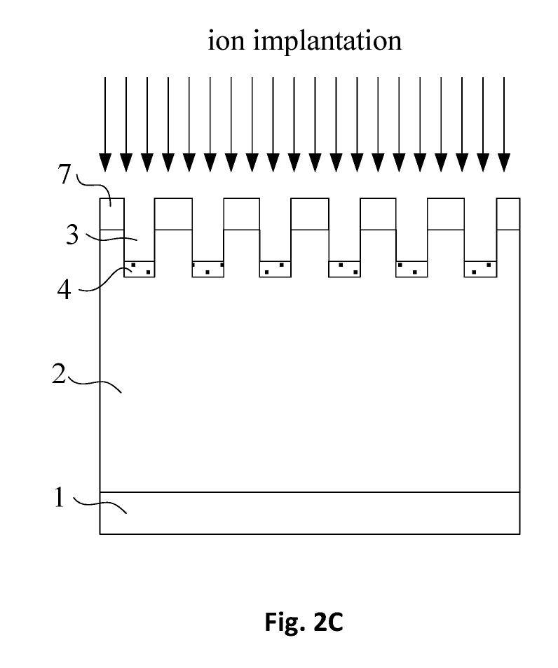

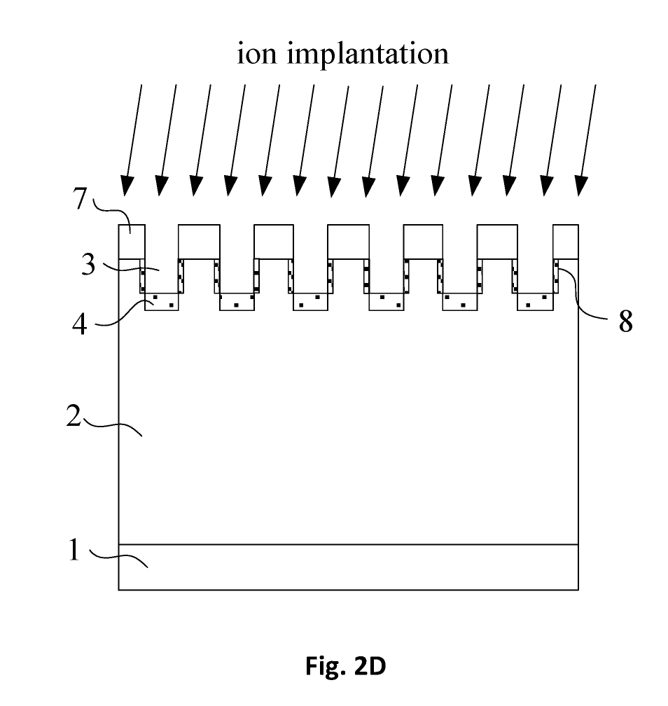

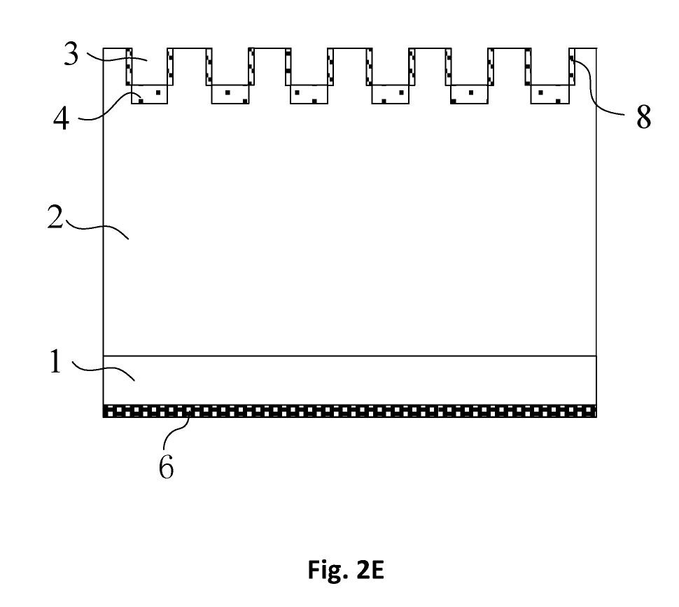

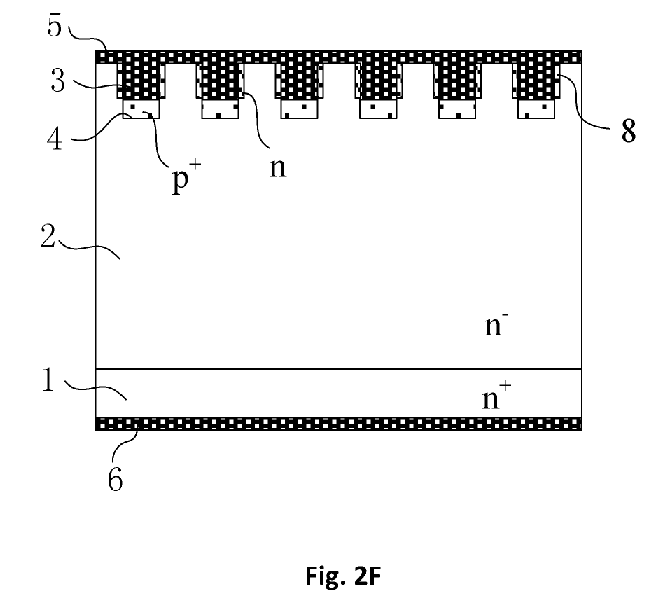

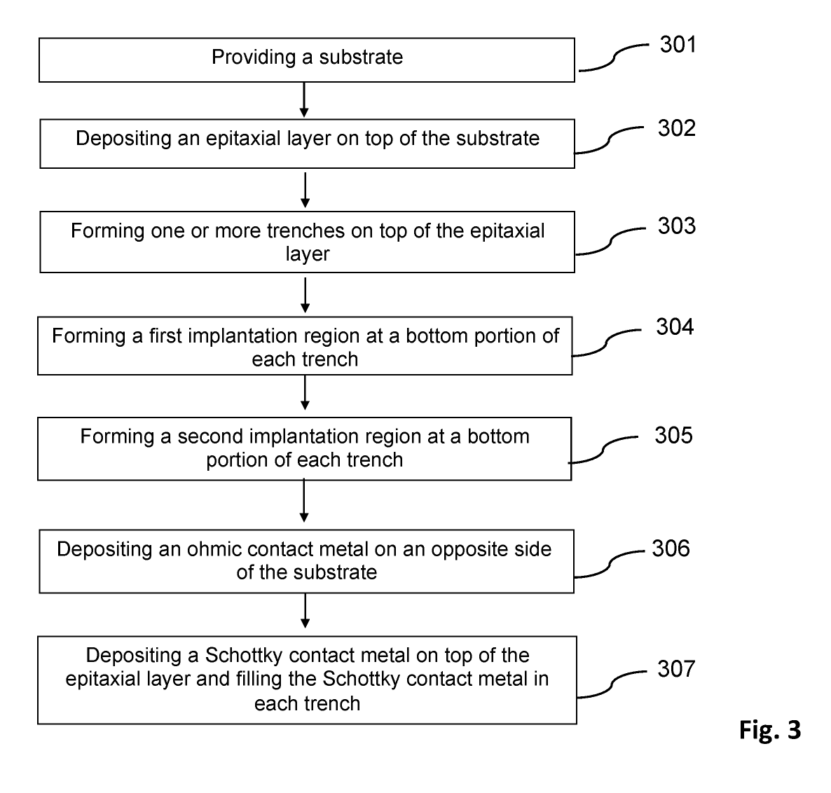

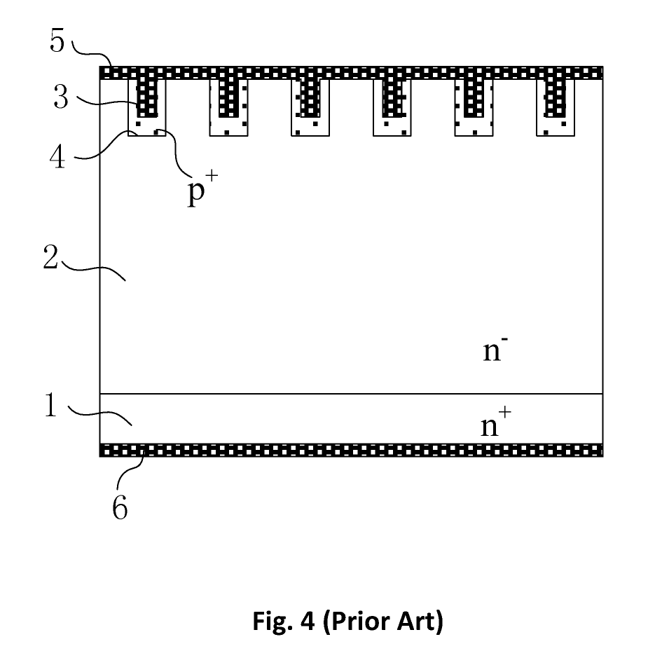

In another aspect, referring to FIGS. 2A˜2F and 3, which show a process flow for manufacturing the SiC trench type Schottky diode. The manufacturing method of the SiC trench type Schottky diode may include following steps: step 301: providing a substrate 1, step 302: depositing an epitaxial layer 2 onto the substrate 1, step 303: forming one or more trenches 3 on top of the epitaxial layer 2, step 304: forming a first implantation region 4 in a bottom portion of each trench 3, step 305: forming a second implantation region 8 in the sidewall of the trench 3, step 306: depositing an ohmic contact metal 6 on an opposite side of the substrate 1, and step 307: depositing a Schottky contact metal 5 on top of the epitaxial layer 2 and filling the Schottky contact metal 5 in each trench 3.

In one embodiment, the substrate 1 in step 301 may be an N⁺ type SiC, and the epitaxial layer 2 in step 302 may be an N-type SiC on top of the substrate 1. In another embodiment, the step 303 of forming one or more trenches 3 may include a step of patterning and etching the epitaxial layer 2 to form the trenches 3.

In still another embodiment, the step 304 of forming a first implantation region 4 may include a step of doping P-type impurity into a bottom portion of each trench 3, and the step of forming a second implantation region 8 may include a step of doping N-type impurity into the sidewall of each trench 3. It is noted that the step 307 of depositing Schottky contact metal 5 on top of the epitaxial layer 2 is to form a Schottky junction between the Schottky contact metal 5 and the epitaxial layer 2, and filling the Schottky contact metal 5 in each trench 3 can also create a Schottky junction between the trench 3 and the epitaxial layer 2.

Comparing with conventional trench type junction barrier Schottky diodes, the present invention is advantageous because the N-type impurity is doped into the sidewall of each trench 3 to reduce forward voltage drop of the trench type junction barrier Schottky diode, and the P-type region in the bottom of the trench 3 is remained for the reverse benefits with the electric field shielding effects.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A Schottky diode comprising:
a substrate;
an epitaxial layer deposited on one side of the substrate;
one or more trenches formed on top of the epitaxial layer;
a first implantation region formed at a bottom portion of each trench;
a second implantation region formed at a sidewall portion of each trench;
an ohmic contact metal deposited on the other side of the substrate; and
a Schottky contact metal deposited onto the epitaxial layer and filled each trench to form a Schottky junction between the Schottky contact metal and the epitaxial layer, and between each trench and the second implantation region.

2. The Schottky diode of claim 1, wherein the first implantation region is doped with P-type material, and the second implantation region is doped with N-type material.

3. The Schottky diode of claim 1, wherein the substrate is made by N⁺ type Silicon Carbide (SiC) and the epitaxial layer is made by N⁻ type SiC.

4. The Schottky diode of claim 1, wherein each trench is formed by etching the epitaxial layer with a depth ranging from 1 to 50000 angstrom.

5. The Schottky diode of claim 1, wherein thickness of the first implantation region is ranging from 1 to 10000 angstrom.

6. The Schottky diode of claim 1, wherein thickness of the second implantation region is ranging from 1 to 10000 angstrom.

7. The Schottky diode of claim 1, wherein the ohmic contact metal is selected from nickel, silver or platinum.

8. A method of manufacturing a Schottky diode comprising steps of:
providing a substrate,
depositing an epitaxial layer on top of the substrate,
forming one or more trenches on top of the epitaxial layer,
forming a first implantation region in a bottom portion of each trench,
forming a second implantation region in a sidewall portion of the trench,
depositing an ohmic contact metal on an opposite side of the substrate, and
depositing a Schottky contact metal on top of the epitaxial layer and filling the Schottky contact metal in each trench.

9. The method of manufacturing a Schottky diode of claim 8, wherein the substrate is made by an N⁺ type SiC, and the epitaxial layer is made by an N-type SiC on top of the substrate.

10. The method of manufacturing a Schottky diode of claim 8, wherein the step of forming a first implantation region includes a step of doping P-type impurity into a bottom portion of each trench.

11. The method of manufacturing a Schottky diode of claim 8, wherein the step of forming a second implantation region includes a step of doping N-type impurity into a sidewall portion of each trench.

12. The method of manufacturing a Schottky diode of claim 8, wherein the step of forming one or more trenches 3 may include a step of patterning and etching the epitaxial layer to form the trenches.

13. The method of manufacturing a Schottky diode of claim 8, wherein the ohmic contact metal is selected from nickel, silver or platinum.
